(19) United States
(12) Patent Application Publication
(10) Pub. No.: US 2026/0033351 A1
(43) Pub. Date: Jan. 29, 2026

(54) STACKED DIE SEMICONDUCTOR PACKAGE INCLUDING AN ARRAY OF PILLAR STRUCTURES

(71) Applicant: Micron Technology, Inc., Boise, ID (US)

(72) Inventors: See Hiong LEOW, Singapore (SG); Hong Wan NG, Singapore (SG); Chin Hui CHONG, Singapore (SG); Kelvin Aik Boo TAN, Singapore (SG); Seng Kim YE, Singapore (SG); Ling PAN, Singapore (SG)

(21) Appl. No.: 19/249,349

(22) Filed: Jun. 25, 2025

Related U.S. Application Data
(60) Provisional application No. 63/675,385, filed on Jul. 25, 2024.

(51) Int. Cl. H01L 23/00; H01L 21/48; H01L 23/31; H01L 23/538; H01L 25/04

(52) U.S. Cl. CPC H01L 24/13; H01L 21/4885; H01L 23/3128; H01L 23/538; H01L 24/16; H01L 24/81; H01L 25/043; H01L 2224/13017; H01L 2224/13025; H01L 2224/1319; H01L 2224/16145; H01L 2224/8114

(57) ABSTRACT

Implementations described herein relate to various semiconductor device assemblies. In some implementations, a semiconductor device assembly includes a substrate, a first integrated circuit die over the substrate including a first recess that penetrates into a first edge of the first integrated circuit die, and a second integrated circuit die over the first integrated circuit die including a second recess that penetrates into a second edge of the second integrated circuit die. The semiconductor device assembly includes a pillar structure that uses the first recess and the second recess to align perimeters of the first integrated circuit die and the second integrated circuit die.

### CROSS-REFERENCE TO RELATED APPLICATION

This patent application claims priority to U.S. Provisional Patent Application No. 63/675,385, filed on Jul. 25, 2024, entitled “STACKED DIE SEMICONDUCTOR PACKAGE INCLUDING AN ARRAY OF PILLAR STRUCTURES,” and assigned to the assignee hereof. The disclosure of the prior application is considered part of and is incorporated by reference into this patent application.

### TECHNICAL FIELD

The present disclosure generally relates to semiconductor devices and methods of forming semiconductor devices. For example, the present disclosure relates a stacked die semiconductor package including an array of pillar structures.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIGS. 1A-1C are diagrams related to an example apparatus that may be manufactured using techniques described herein.

FIG. 2 is a diagram of an example memory device that may be manufactured using techniques described herein.

FIG. 3 is a diagram of example implementations of pillar structures described herein.

FIG. 4 is a flowchart of an example method of forming an integrated assembly or memory device having pillar structures.

FIG. 5 is a flowchart of an example method of forming an integrated assembly or memory device having pillar structures.

FIG. 6 is a flowchart of an example method of forming an integrated assembly or memory device having pillar structures.

FIGS. 7A-7D describe an example series of semiconductor manufacturing operations that may be performed to form a portion of a stacked die semiconductor package including an array of pillar structures described herein.

FIGS. 8A-8D describe an example series of semiconductor manufacturing operations that may be performed to form a portion of a stacked die semiconductor package including an array of pillar structures described herein.

FIG. 9 is a diagram of an example integrated assembly described herein.

FIG. 10 is a diagram of an example integrated assembly described herein.

### DETAILED DESCRIPTION

In the rapidly evolving field of semiconductor device fabrication, particularly within memory technologies such as universal flash storage (UFS), there exists a demand to increase storage capacities while concurrently reducing the thickness (e.g., z-height) of semiconductor packages to facilitate thinner consumer devices. As a result, manufacturers are compelled to explore methods for stacking increasingly thinner integrated circuit (IC) dies within a single package.

However, this miniaturization effort is not without its technical challenges. The traditional use of die attach materials, such as die attach film (DAF) or film-over-wire (FOW), contributes a significant portion to the overall height of the die stack, thereby obstructing efforts to satisfy thickness thresholds. Moreover, the use of thinner IC dies—while needed for stack height reduction—raises fragility concerns. Thinner IC dies are inherently more prone to damage, exhibiting higher rates of cracking under stress during the manufacturing process.

Additionally, reducing IC die thickness often correlates with an increased susceptibility to warping, which further complicates manufacturing processes and can negatively impact yields. The presence of foreign materials, which may become trapped between IC dies during the stacking process, can induce particle damage on die surfaces, compounding the challenge of achieving targeted yield thresholds. The drive towards thinner IC die stacks for high-capacity devices (universal flash storage (UFS) devices, high bandwidth memory (HBM) devices, multi-chip (MCP) packages, or hybrid memory cube (HMC) devices, among other examples) while maintaining or improving production yields and handling robustness presents a complex array of technical problems that necessitate inventive solutions.

Some implementations described herein present an approach to semiconductor package assembly that promotes higher memory density without increasing the overall semiconductor package thickness. For example, a semiconductor package may include a substrate and a series of stacked IC dies over the substrate. The IC dies may have recesses for alignment and bearing surfaces separated by a pillar structure, which eliminates the need for traditional die attach material (e.g., die attach films), allowing for thicker, more robust dies and reducing the risk of die cracking. Alternatively, the IC dies may have plated through-holes through which a pillar structure passes and electrically couples the IC dies.

In some implementations, the pillar structure may be a tapered or tiered pillar structure, providing mechanical precision in aligning and stacking the dies. Additionally, mold compounds or wire bond loops may be implemented between co-facing surfaces of the IC dies for structural support and electrical connectivity.

Alternatively, and in some implementations, the pillar structure may have a substantially consistent diameter. Additionally, or alternatively, the pillar structure may be a conductive pillar structure, permitting electrical coupling of the IC dies and/or the substrate.

Such implementations may facilitate construction of semiconductor packages that balance the constraints of thickness thresholds with the demand for high memory capacity in compact footprints. By removing the need for die attach materials and maintaining IC die thicknesses to reduce the risk of die cracking, there is an increase in structural integrity and a decrease in potential contamination, which may lead to improved production yields. Furthermore, the elimination of curing processes for the die attach materials may improve manufacturing cycles, saving 1-2 days of cycle time. Through these enhancements, the pillar structure-based stacking method contributes to a reduction in cycle times and supports versatile adaptation to various semiconductor package thickness thresholds and density specifications.

In this way, the semiconductor package may promote increased reliability and manufacturing efficiency. Moreover, by improving the quality and reliability of the semiconductor package by maintaining IC die thicknesses to reduce a likelihood of IC die cracking, an amount of resources used to support a market consuming the semiconductor device (e.g., raw materials, semiconductor manufacturing tools, labor, and/or computing resources) is reduced.

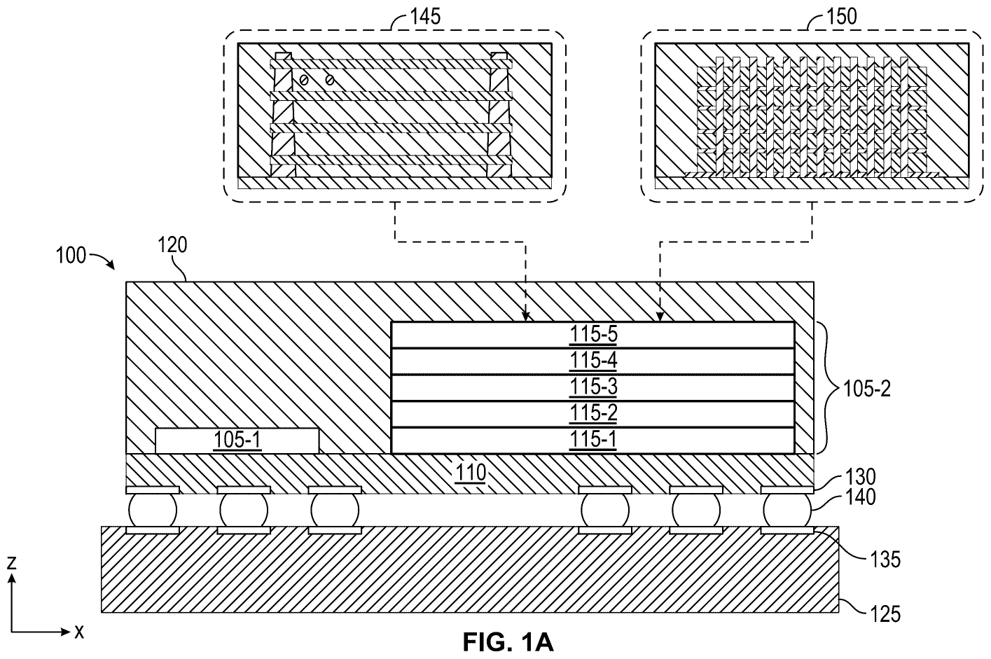

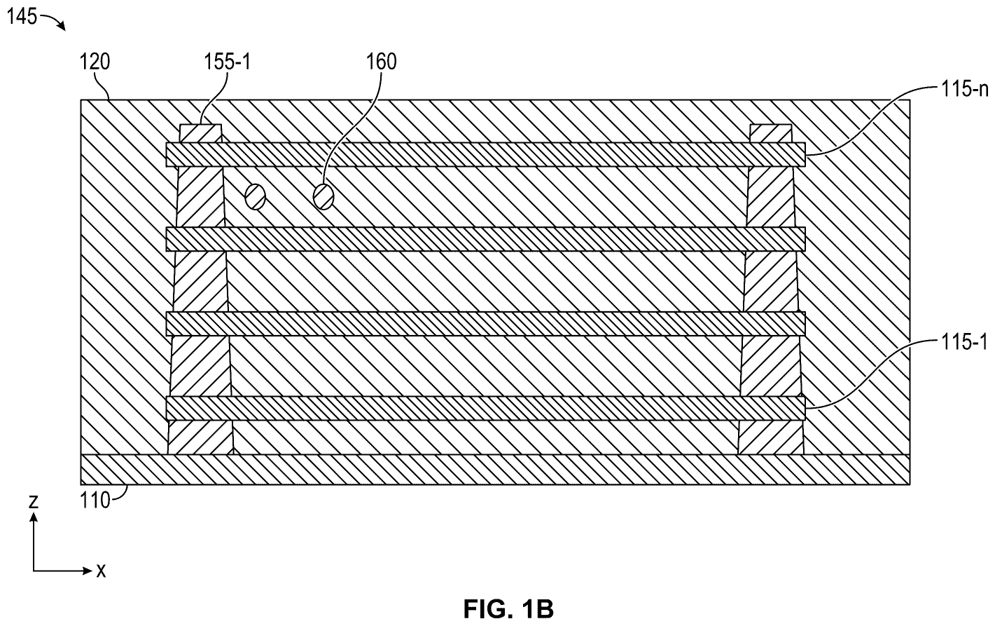

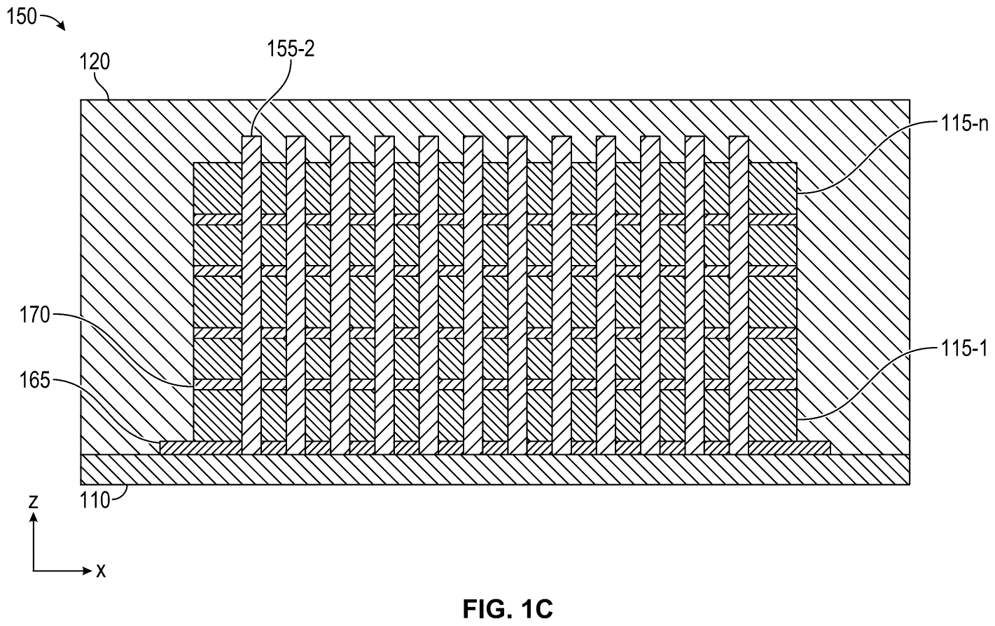

FIGS. 1A-1C are diagrams related to an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1A, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1A, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1A shows the dies 115 stacked in a straight stack (e.g., with aligned die edges), in some implementations, the dies 115 may be stacked in a different arrangement, such as a shingle stack (e.g., with die edges that are not aligned, which provides space for wire bonding near the edges of the dies 115).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

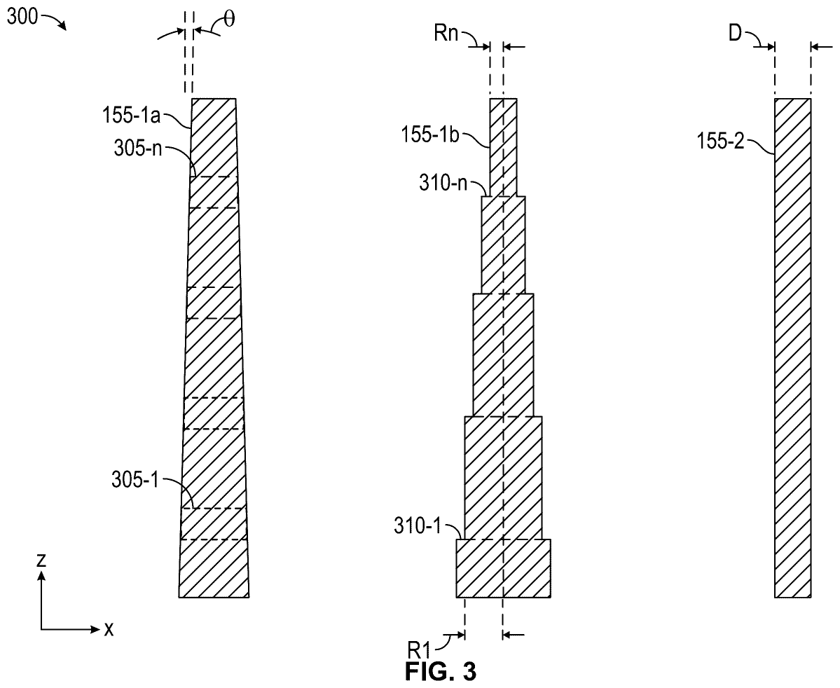

As described in greater detail in connection with FIG. 1B, FIG. 3, and elsewhere herein, an implementation 145 of a die stacking technique in the apparatus 100 may include an array of pillar structures that are distributed around a perimeter of the dies 115 to align and/or separate the dies 115. Alternatively, and as described in greater detail in connection with FIG. 1C, FIG. 3, and elsewhere herein, an implementation 150 of a die stacking technique in the apparatus 100 may include an array of pillar structures that penetrate through the dies 115 to align and/or electrically couple the dies 115.

As shown in FIG. 1B, implementation 145 includes a stack of dies 115 (e.g., the dies 115-1 through 115-n) over the substrate 110. As further shown in FIG. 1B, an array of pillar structures 155-1 may be located around perimeters of the dies 115 to position and/or align the dies 115. The pillar structures 155-1 may be an insulative (e.g., dielectric) material and include bearing surfaces that separate the dies 115 and allow for wire bond loops 160 and/or portions of the casing 120 between co-facing surfaces of the dies 115. In implementation 145, and as shown in FIG. 1B, the casing 120 surrounds the pillar structures 155-1. Furthermore, and as shown in FIG. 1B, implementation 145 allows for the exclusion of DAF between the dies 115 to satisfy a die thickness threshold (e.g., a die thickness threshold greater than or equal to approximately 40 microns) for robustness purposes.

As shown in FIG. 1C, implementation 150 includes a stack of dies 115 (e.g., the dies 115-1 through 115-n) over the substrate 110. As further shown in FIG. 1C, an array of pillar structures 155-2 may penetrate through the dies 115 to position and/or align the dies 115. Furthermore, the pillar structures 155-2 may be electrically conductive and electrically couple one or more of the dies 115 and/or the substrate 110. In some implementations, and as shown in FIG. 1C, a thermal compression material layer 170 (e.g., a thermal pad, a thermal adhesive tape, a phase change material, or a thermal grease) is between co-facing surfaces of one or more pairs of vertically-adjacent dies 115 to promote thermal conduction and/or dissipation of heat from the dies 115.

As indicated above, FIGS. 1A-IC are provided as an example. Other examples may differ from what is described with regard to FIGS. 1A-IC.

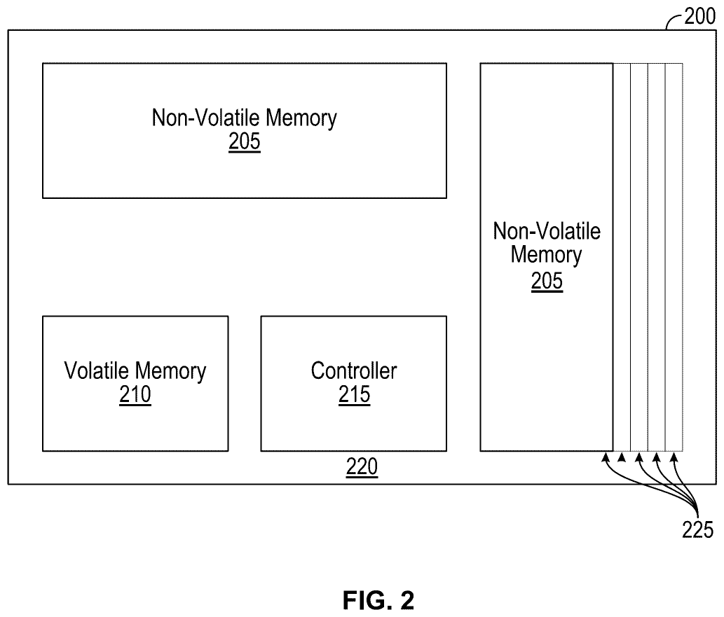

FIG. 2 is a diagram of an example memory device 200 that may be manufactured using techniques described herein. The memory device 200 is an example of the apparatus 100 described above in connection with FIGS. 1A-1C, including the implementation 145 of the pillar structures 155-1 and/or the implementation 150 of the pillar structures 155-2. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

FIG. 3 is a diagram of example implementations 300 of pillar structures described herein (e.g., the pillar structure 155-1a, the pillar structure 155-1b, and the pillar structure 155-2). The pillar structure 155-1a and/or the pillar structure 155-1b may be used as part of implementation 145, as described in connection with FIG. 1B. The pillar structure 155-2 may be used as part of implementation 150, as described in connection with FIG. 1C.

The pillar structure 155-1a and/or the pillar structure 155-1b may be formed from an insulative (e.g., dielectric) material. Examples of the insulative material include polyimide, polyetheretherketone, polycarbonate, photopolymer resin, or another suitable insulative material, among other examples.

As shown in FIG. 3, the pillar structure 155-1a may be a tapered pillar structure having surfaces (e.g., angled surfaces) tapered at an angle θ. As an example, the angle θ may be included in a range of approximately 2 degrees to approximately 10 degrees. However, other values and ranges for the angle θ are within the scope of the present disclosure.

The pillar structure 155-1a may have different cross-sectional shapes (e.g., cross-sectional shapes from a top-view perspective). For example, and in some implementations, the pillar structure 155-1a may include a circular cross-sectional shape, with tapering along circular, perimeter surfaces at the angle θ. Alternatively, and in some implementations, the pillar structure 155-1a may include a semi-circular cross-sectional shape, with tapering along semi-circular, perimeter surfaces at the angle θ. In some implementations, the pillar structure 155-1a may include a rectangular cross-sectional shape, with tapering along rectangular, perimeter surfaces at the angle θ.

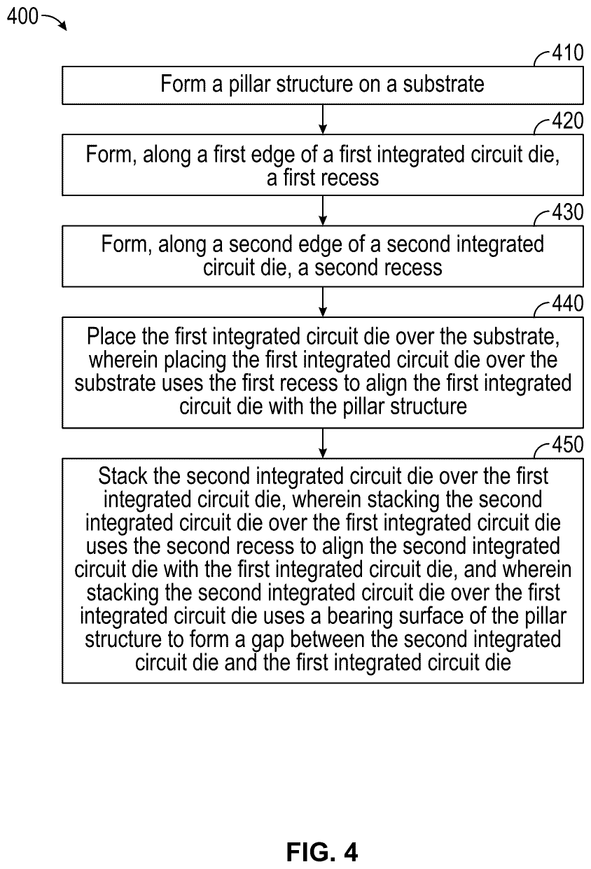

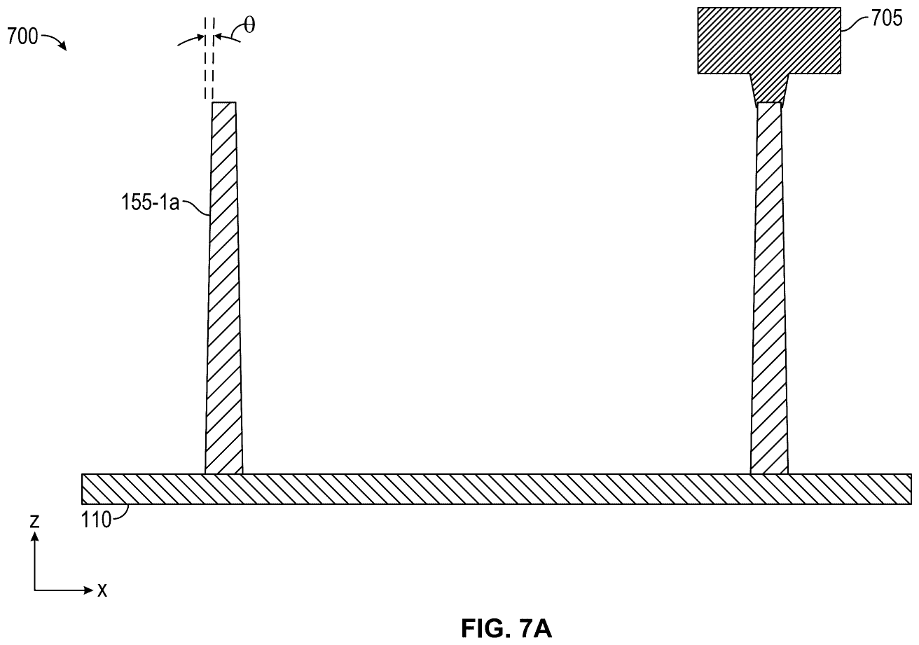

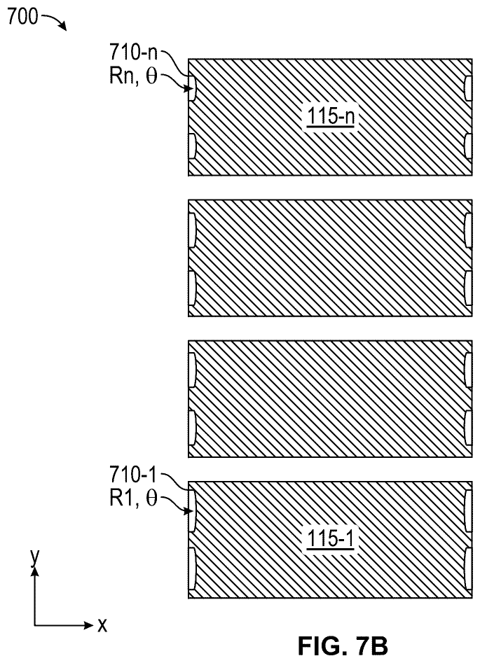

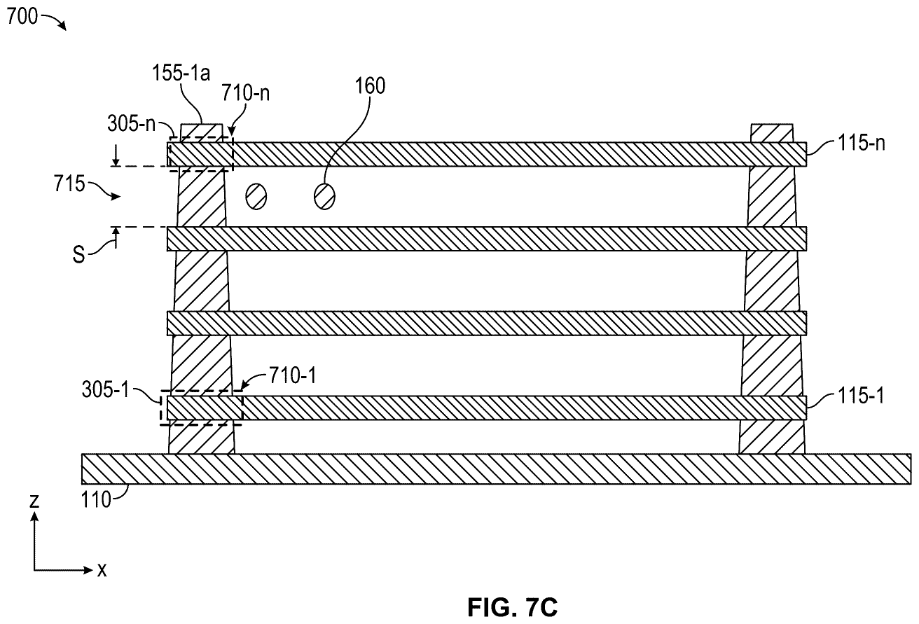

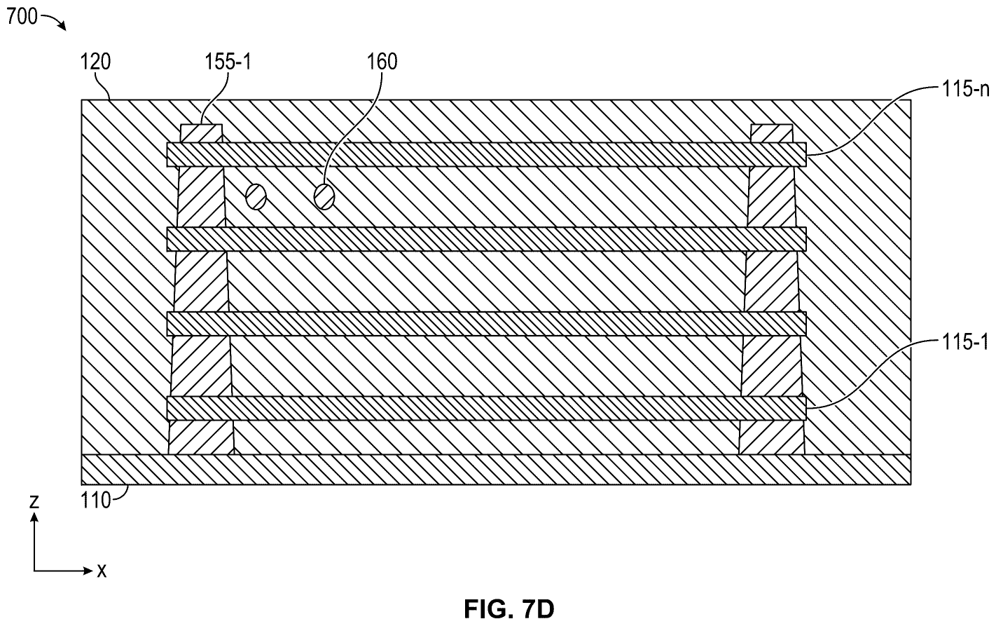

Portions of the pillar structure 155-1a may correspond to bearing surfaces 305-1 through 305-n, against which IC dies (e.g., the IC dies 115-1 through 115-n) may be aligned, captured, and/or supported. As described in greater detail in connection with FIGS. 4 and 7B, a progressive series of IC dies may include recesses having interior, angled surfaces that complement (e.g., inversely match) the angle θ along bearing surfaces 305-1 through 305-n.

As shown in FIG. 3, the pillar structure 155-1b may be a tiered pillar structure. Tiers of the pillar structure 155-1b may correspond to bearing surfaces 310-1 through 310-n, against which IC dies (e.g., the dies 115-1 through 115-n) may be aligned, captured, and/or supported. Portions of the pillar structure 155-1b above the bearing surfaces 310-1 through 310-n may have radii of curvature R1 through Rn, where R1 is greater than Rn (or, conversely, where Rn is less than R1). As described in greater detail in connection with FIG. 7B, a series of IC dies may include recesses having radii of curvature that approximate radii of curvature R1 through Rn.

The pillar structure 155-1b may be formed from a conductive material. Examples of the conductive material include a matrix material infused with copper powder, aluminum powder, nickel powder, or another suitable conductive powder, among other examples.

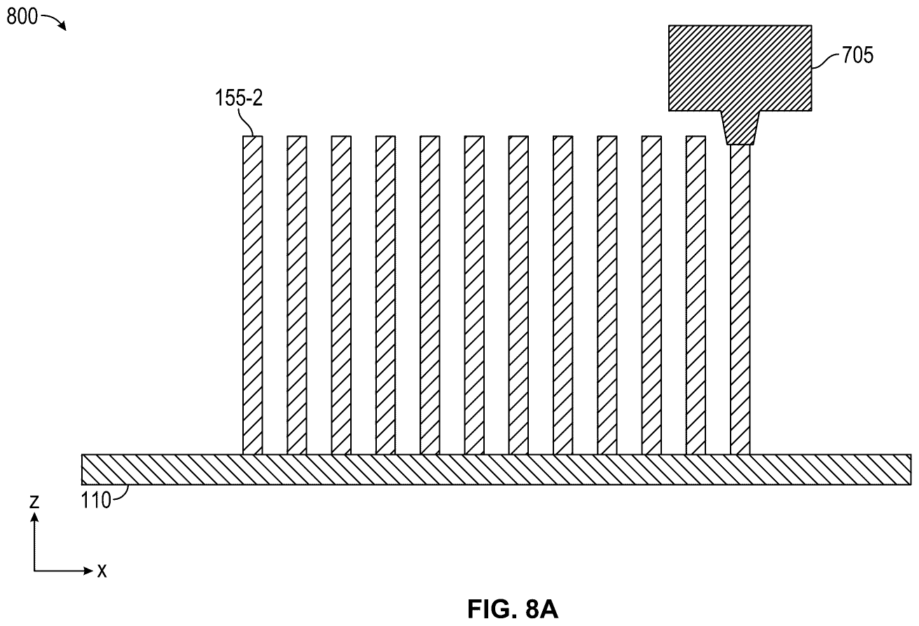

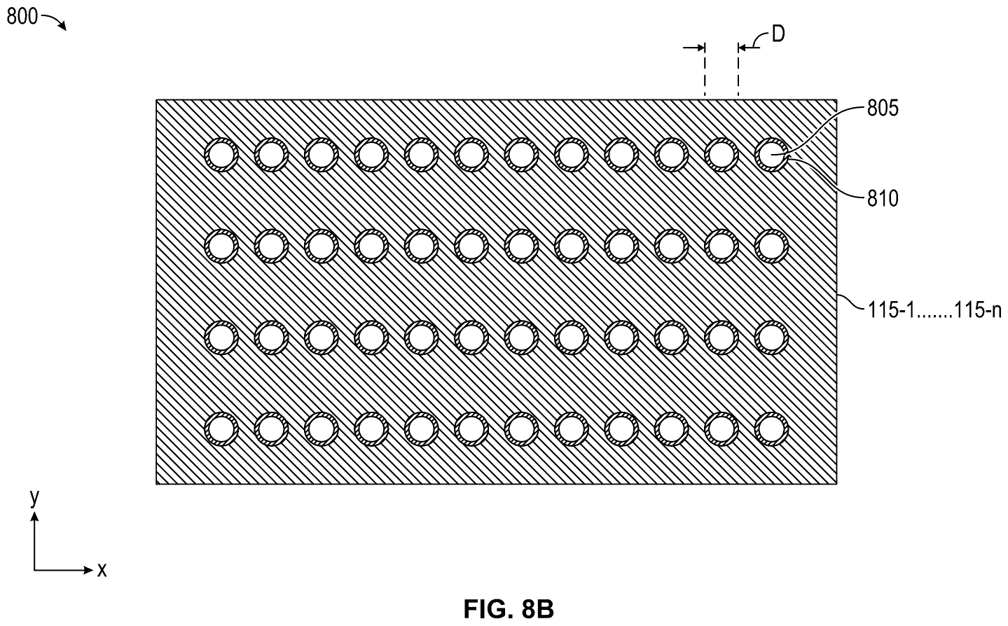

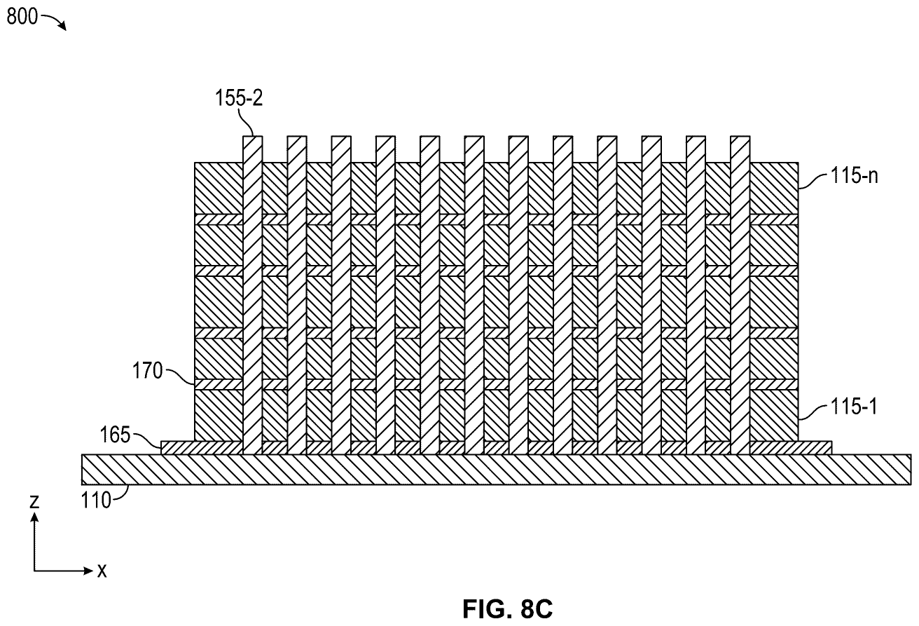

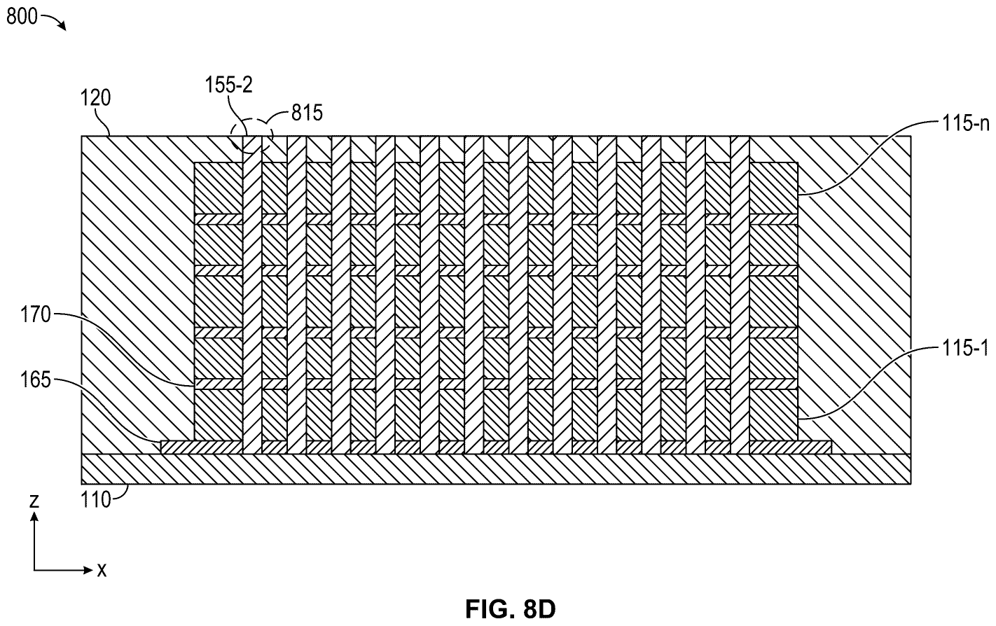

As shown in FIG. 3, the pillar structure 155-2 may have a substantially consistent diameter D. As described in greater detail in connection with FIG. 8B, a series of IC dies may include plated through-holes (vias) having diameters that approximate the diameter D to electrically couple with the pillar structure 155-2.

As indicated above, FIG. 3 is provided as one or more examples. Other examples may differ from what is described with regard to FIG. 3

As described in greater detail in connection with FIGS. 4-10, aspects of FIGS. 1-3 may facilitate die stacking methods that balance the constraints of semiconductor package thickness thresholds with the demand for high memory capacity in compact footprints. By removing the need for die attach materials and maintaining a thickness of the dies to reduce a risk of die cracking, there is an increase in structural integrity and a decrease in potential contamination, which may lead to improved production yields. Furthermore, the elimination of curing processes for the die attach materials may improve manufacturing cycles, saving 1-2 days of cycle time. The pillar structure-based die stacking methods may contribute to a reduction in cycle times and supports versatile adaptation to various semiconductor package thickness thresholds and density specifications.

FIG. 4 is a flowchart of an example method 400 of forming an integrated assembly or memory device having pillar structures. In some implementations, and as described in greater detail in connection with FIGS. 7A-7D, one or more semiconductor processing tools of a semiconductor package manufacturing facility (e.g., a three-dimensional printing tool, an etch tool, a griding tool, a laser tool, a deposition tool, a mold tool, a pick-and-place tool, or a reflow tool) may perform or be configured to perform one or more aspects of the method 400. Thus, means for performing the method 400 may include the one or more semiconductor processing tools and/or one or more components of the one or more semiconductor processing tools. Additionally, or alternatively, a non-transitory computer-readable medium may store one or more instructions that, when executed by the one or more semiconductor processing tools, cause the one or more semiconductor processing tools to perform the method 400.

As shown in FIG. 4, the method 400 may include forming a pillar structure (e.g., the pillar structure 155-1a or the pillar structure 155-1b) on a substrate (e.g., the substrate 110) (block 410). As further shown in FIG. 4, the method 400 may include forming, along a first edge of a first IC die (e.g., the die 115-1), a first recess (block 420). As further shown in FIG. 4, the method 400 may include forming, along a second edge of a second IC die (e.g., the die 115-n), a second recess (block 430). As further shown in FIG. 4, the method 400 may include placing the first IC die over the substrate, wherein placing the first IC die over the substrate uses the first recess to align the first IC die with the pillar structure (block 440). As further shown in FIG. 4, the method 400 may include stacking the second IC die over the first IC die, wherein stacking the second IC die over the first IC die uses the second recess to align the second IC die with the first IC die, and wherein stacking the second IC die over the first IC die uses a bearing surface (e.g., the bearing surface 305-n or the bearing surface 310-n) of the pillar structure to form a gap between the second IC die and the first IC die (block 450).

The method 400 may include additional aspects, such as any single aspect or any combination of aspects described below and/or described in connection with one or more other methods or operations described elsewhere herein.

In a first aspect, forming the pillar structure includes forming the pillar structure using a three-dimensional printing operation.

In a second aspect, alone or in combination with the first aspect, forming the first recess or the second recess includes forming the first recess or the second recess using a laser ablation operation, forming the first recess or the second recess using an etching operation, or forming the first recess or the second recess using a grinding operation.

In a third aspect, alone or in combination with one or more of the first and second aspects, forming the pillar structure includes forming a tapered pillar structure (e.g., the pillar structure 155-1a) having an angled surface, and wherein forming the first recess and the second recess includes forming interior, angled surfaces that complement the angled surface of the pillar structure.

In a fourth aspect, alone or in combination with one or more of the first through third aspects, forming the pillar structure includes forming a tiered pillar structure (e.g., the pillar structure 155-1b).

In a fifth aspect, alone or in combination with one or more of the first through fourth aspects, the method 400 includes forming a wire bond loop (e.g., the wire bond loop 160) in the gap between the first IC die and the second IC die.

In a sixth aspect, alone or in combination with one or more of the first through fifth aspects, the method 400 includes forming a casing (e.g., the casing 120) that fills the gap and that surrounds the first IC die, the second IC die, and the pillar structure.

In a seventh aspect, alone or in combination with one or more of the first through sixth aspects, the method 400 includes forming interconnect structures (e.g., the solder balls 140) on the substrate, and joining the interconnect structures with a redistribution structure as part of forming a package-on-package assembly that includes the first IC die, the second IC die, and the pillar structure.

Although FIG. 4 shows example blocks of the method 400, in some implementations, the method 400 may include additional blocks, fewer blocks, different blocks, or differently arranged blocks than those depicted in FIG. 4. In some implementations, the method 400 may include forming the apparatus 100, an integrated assembly that includes the apparatus 100, any part described herein of the apparatus 100 (e.g., the pillar structure 155-1a or the pillar structure 155-1b) and/or any part described herein of an integrated assembly that includes the apparatus 100. For example, the method 400 may include forming the memory device 200.

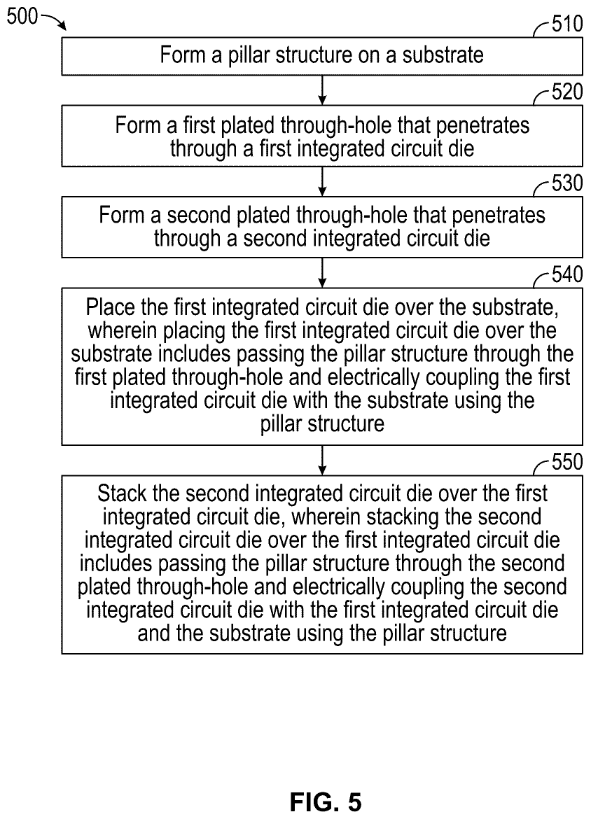

FIG. 5 is a flowchart of an example method 500 of forming an integrated assembly or memory device having pillar structures. In some implementations, and as described in greater detail in connection with FIGS. 8A-8D, one or more semiconductor processing tools of a semiconductor package manufacturing facility (e.g., a three-dimensional printing tool, an etch tool, a griding tool, a laser tool, a deposition tool, a mold tool, a pick-and-place tool, a testing tool, or a reflow tool) may perform or be configured to perform one or more aspects of the method 500. Thus, means for performing the method 500 may include the one or more semiconductor processing tools and/or one or more components of the one or more semiconductor processing tools. Additionally, or alternatively, a non-transitory computer-readable medium may store one or more instructions that, when executed by the one or more semiconductor processing tools, cause the one or more semiconductor processing tools to perform the method 500.

As shown in FIG. 5, the method 500 may include forming a pillar structure (e.g., the pillar structure 155-2) on a substrate (e.g., the substrate 110) (block 510). As further shown in FIG. 5, the method 500 may include forming a first plated through-hole that penetrates through a first IC die (e.g., the die 115-1) (block 520). As further shown in FIG. 5, the method 500 may include forming a second plated through-hole that penetrates through a second IC die (e.g., the die 115-n) (block 530). As further shown in FIG. 5, the method 500 may include placing the first IC die over the substrate, wherein placing the first IC die over the substrate includes passing the pillar structure through the first plated through-hole and electrically coupling the first IC die with the substrate using the pillar structure (block 540). As further shown in FIG. 5, the method 500 may include stacking the second IC die over the first IC die, wherein stacking the second IC die over the first IC die includes passing the pillar structure through the second plated through-hole and electrically coupling the second IC die with the first IC die and the substrate using the pillar structure (block 550).

The method 500 may include additional aspects, such as any single aspect or any combination of aspects described below and/or in connection with one or more other methods described elsewhere herein.

In a first aspect, forming the pillar structure includes forming the pillar structure using a three-dimensional printing operation.

In a second aspect, alone or in combination with the first aspect, the method 500 includes forming a casing (e.g., the casing 120) that surrounds the first IC die, the second IC die, and the pillar structure.

In a third aspect, alone or in combination with one or more of the first and second aspects, the method 500 includes testing at least one of the first IC die and the second IC die by probing a tip of the pillar structure that is exposed at a surface of the casing.

In a fourth aspect, alone or in combination with one or more of the first through third aspects, the method 500 includes forming interconnect structures (e.g., the solder balls 140) on the substrate, and joining the interconnect structures with a redistribution structure as part of forming a package-on-package assembly that includes the first IC die, the second IC die, and the pillar structure.

In a fifth aspect, alone or in combination with one or more of the first through fourth aspects, the pillar structure is a first pillar structure, and further comprising joining the first pillar structure with a second pillar structure as part of forming a package-on-package assembly that includes the first IC die, the second IC die, the first pillar structure, and the second pillar structure.

In a sixth aspect, alone or in combination with one or more of the first through fifth aspects, joining the first pillar structure and the second pillar structure includes joining the first pillar structure and the second pillar structure using an interconnect bump that directly couples an end of the first pillar structure with an end of the second pillar structure.

In a seventh aspect, alone or in combination with one or more of the first through sixth aspects, the method 500 includes forming a thermal compression material between the first IC die and the second IC die.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming the apparatus 100, an integrated assembly that includes the apparatus 100, any part described herein of the apparatus 100 (e.g., the pillar structure 155-2) and/or any part described herein of an integrated assembly that includes the apparatus 100. For example, the method 500 may include forming the memory device 200.

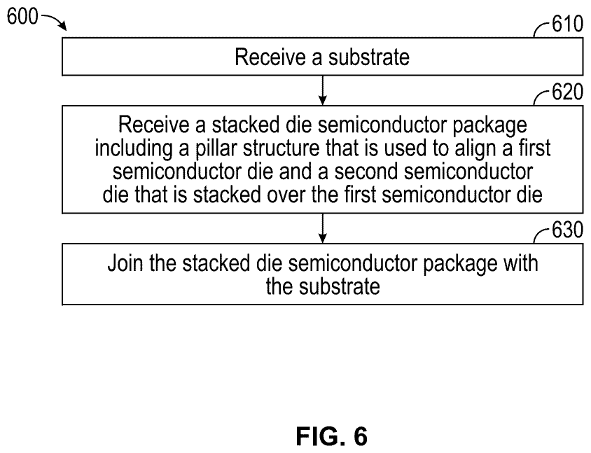

FIG. 6 is a flowchart of an example method 600 of forming an integrated assembly or memory device having pillar structures. In some implementations, one or more semiconductor processing tools of a semiconductor package manufacturing facility (e.g., a pick-and-place tool or a reflow tool) may perform or be configured to perform one or more aspects of the method 600. Thus, means for performing the method 600 may include the one or more semiconductor processing tools and/or one or more components of the one or more semiconductor processing tools. Additionally, or alternatively, a non-transitory computer-readable medium may store one or more instructions that, when executed by the one or more semiconductor processing tools, cause the one or more semiconductor processing tools to perform the method 600.

As shown in FIG. 6, the method 600 may include receiving a substrate (a printed circuit board (PCB), an interface board, or a host computing board, among other examples) (block 610). As further shown in FIG. 6, the method 600 may include receiving a stacked die semiconductor package (e.g., the apparatus 100) including a pillar structure (e.g., the pillar structure 155-1a, the pillar structure 155-1b, or the pillar structure 155-2) that is used to align a first semiconductor die (e.g., the die 115-1) and a second semiconductor die (e.g., the die 115-n) that is stacked over the first semiconductor die (block 620). As further shown in FIG. 6, the method 600 may include joining the stacked die semiconductor package with the substrate (block 630).

The method 600 may include additional aspects, such as any single aspect or any combination of aspects described below and/or in connection with one or more other methods described elsewhere herein.

Although FIG. 6 shows example blocks of the method 600, in some implementations, the method 600 may include additional blocks, fewer blocks, different blocks, or differently arranged blocks than those depicted in FIG. 6. In some implementations, the method 600 may include forming the apparatus 100, an integrated assembly that includes the apparatus 100, any part described herein of the apparatus 100 (e.g., the pillar structure 155-1a, the pillar structure 155-1b, and/or the pillar structure 155-2) and/or any part described herein of an integrated assembly that includes the apparatus 100. For example, the method 600 may include forming the memory device 200.

FIGS. 7A-7D describe an example series of semiconductor manufacturing operations 700 that may be performed to form a portion of a stacked die semiconductor package including an array of pillar structures described herein (e.g., the apparatus 100 including the pillar structures 155-1a or 155-1b). One or more of the series of semiconductor manufacturing operations 700 may correspond to one or more of the blocks described in connection with the method 400 of FIG. 4, among other examples.

As shown in FIG. 7A, the series of semiconductor manufacturing operations 700 may include an additive manufacturing operation (e.g., a three-dimensional (3D) printing operation) to form an array of the pillar structures 155 over and/or on the substrate 110. As an example, a printing tool 705 may be used be used to perform an additive manufacturing operation that uses a printing technique (e.g., a fused filament fabrication (FFF) printing technique, a fused deposition modeling (FDM) printing technique, a stereolithography (SLA) printing technique, or a digital light processing (DLP) printing technique) to form the pillar structures 155. As shown in FIG. 7A, the pillar structures 155 may correspond to the pillar structures 155-1a of FIG. 3A having the surfaces tapered at the angle θ. Alternatively, the pillar structures 155 may correspond to the pillar structures 155-1b of FIG. 3A (not shown in FIG. 7A).

As shown in FIG. 7B, the series of operations 700 may include forming recesses 710-1 through 710-n along perimeters of a series of dies 115-1 through 115-n. As an example, and in some implementations, a griding tool may be used to perform a grinding operation to form the recesses 710-1 through 710-n. As another example, and in some implementations, a combination of lithography and etch tools may be used to perform patterning and etching operations to form the recesses 710-1 through 710-n. As another example, and in some implementations, a laser tool may be used to perform a laser ablation operation to form the recesses 710-1 through 710-n.

In some implementations (e.g., an implementation of the stacked die semiconductor package using the pillar structures 155-1a), the recesses 710-1 through 710-n may include interior, angled surfaces that are complementary to angled surfaces of tapered pillar structures (e.g., surfaces of the pillar structures 155-1a that are tapered at the angle θ). Furthermore, and in such implementations, areas of the recesses 710-1 through 710-n may vary to compensate for tapering of a pillar structure (e.g., an area of the recess 710-n may be less than an area of the recess 710-1 to compensate for tapering of the pillar structure 155-1a).

Alternatively, and in some implementations (e.g., an implementation of the stacked die semiconductor package using the pillar structures 155-1b), the recesses 710-1 through 710-n may have radii of curvature that approximate the radii of curvatures of segments of tiered pillar structures (e.g., segments of the tiered pillar structures 155-1b having the radii of curvature R1 through Rn).

As shown in FIG. 7C, the series of operations 700 may include placing the die 115-1 over the substrate 110. In some implementations (e.g., an implementation of the stacked die semiconductor package using the pillar structures 155-1a) and as an example, a pick-and-place tool maybe used to perform a placement operation to place the die 115-1 over the substrate 110 and align the recess 710-1 with the bearing surface 305-1. Alternatively, and in some implementations (e.g., an implementation of the stacked die semiconductor package using the pillar structures 155-1b), a pick-and-place tool may be used to perform a placement operation to place the die 115-1 over the substrate 110 and aligns the recess 710-1 with the bearing surface 310-1 (not shown in FIG. 7C).

As further shown in FIG. 7C, the series of operations 700 may include stacking additional IC dies (e.g., including the die 115-n) over the die 115-1. In some implementations, the bearing surfaces 305-1 through 305-n (or 310-1 through 310-n) may support the dies 115-1 through 115-n and create gaps 715 between co-facing surfaces of vertically-adjacent dies 115.

In some implementations, the gaps 715 may be defined by a separation distance S that is greater than approximately 50 microns. In such a case, and as part of the series of operations 700, a wire bond tool may be used to perform a wire bonding operation to form the wire bond loops 160 in the gaps 715 as part of electrically coupling one or more of the dies 115 and/or the substrate 110. If the separation distance is less than approximately 50 microns, an available space may be insufficient for the wire bond tool perform the wire bonding operation that forms the wire bond loops 160. However, other values and ranges for the separation distance S are within the scope of the present disclosure.

As shown in FIG. 7D, the series of operations 700 may include forming the casing 120. As an example, a mold tool may be used to perform a molding operation to form the casing 120 using an injection molding technique or a transfer molding technique. In some implementations, and as shown in FIG. 7D, the casing 120 may surround the pillar structures 155-1a, the dies 115-1 through 115-n, and/or the wire bond loops 160.

As indicated above, FIGS. 7A-7D are provided as an example. Other examples may differ from what is described with regards to FIGS. 7A-7D.

As described in connection with FIG. 1A, FIG. 1B, FIG. 2, FIG. 3, FIG. 4, and FIGS. 7A-7D, and in some implementations, a semiconductor device assembly (e.g., the apparatus 100 or the memory device 200) includes a substrate (e.g., the substrate 110), a first IC die (e.g., the die 115-1) over the substrate including a first recess (e.g., the recess 710-1) that penetrates into a first edge of the first IC die, and a second IC die (e.g., the die 115-n) over the first IC die including a second recess (e.g., the recess 710-n) that penetrates into a second edge of the second IC die. The semiconductor device assembly includes a pillar structure (e.g., the pillar structure 155-1a or the pillar structure 155-1b) having a first bearing surface (e.g., the bearing surface 305-1 or the bearing surface 310-1) that supports the first IC die and a second bearing surface (e.g., the bearing surface 305-n or the bearing surface 310-n) that supports the second IC die, wherein the pillar structure uses the first recess and the second recess to align perimeters of the first IC die and the second IC die, and wherein the first bearing surface and the second bearing surface separate the first IC die and the second IC die.

FIGS. 8A-8D describe an example series of semiconductor manufacturing operations 800 that may be performed to form a portion of a stacked die semiconductor package including an array of pillar structures described herein (e.g., the apparatus 100 including the pillar structures 155-2). One or more of the series of semiconductor manufacturing operations 800 may correspond to one or more of the blocks described in connection with the method 500 of FIG. 5, among other examples.

As shown in FIG. 8A, the series of semiconductor manufacturing operations 800 may include an additive manufacturing operation (e.g., a 3D printing operation) to form an array of the pillar structures 155-2 over and/or on the substrate 110. As an example, the printing tool 705 may be used be used to perform an additive manufacturing operation that uses a printing technique (e.g., an FFF printing technique, an FDM printing technique, an SLA printing technique, or a DLP printing technique) to form the pillar structures 155-2.

As shown in FIG. 8B, the series of operations 800 may include forming an array of through-holes 805 (e.g., vias) that penetrate through the dies 115-1 through 115-n. Furthermore, the series of operations 800 may include forming a plating 810 (e.g., copper plating, aluminum plating, or nickel plating) on interior surfaces of the through-holes 805 (in other words, the through-holes 805 are plated through-holes). Each of the through-holes 805 with the plating 810 may have an interior diameter that approximates/matches the diameter D of the pillar structure 155-2.

In some implementations, a combination of lithography and etch tools may be used to perform patterning and etching operations to form the through-holes 805. As another example, and in some implementations, a laser tool may be used to perform a laser ablation operation to form the through-holes 805. Additionally, forming the plating 810 may include a deposition tool performing a plating operation to form the plating 810.

As shown in FIG. 8C, the series of operations 800 may include forming an underfill layer 165 (e.g., a layer of an epoxy resin) over and/or on the substrate 110. As an example, forming the underfill layer 165 may include a deposition tool dispensing the underfill layer 165 over and/or on the substrate 110.

Furthermore, and as shown in FIG. 8C, the series of operations 800 may include placing the die 115-1 over the substrate 110 (and/or over the underfill layer 165). As an example, a pick-and-place tool maybe used to perform a placement operation to place the die 115-1 over the substrate 110, where placing the die 115-1 over the substrate 110 passes the array of the pillar structures 155-2 through the array of the through-holes 805 and electrically couples the die 115-1 with the substrate 110.

As further shown in FIG. 8C, the series of operations 800 may include forming the thermal compression material layer 170 over and/or on the die 115-1. As an example, a deposition tool may be used to performing a dispense operation to form the thermal compression material layer 170 over and/or on the die 115-1.

As further shown in FIG. 8C, the series of operations 800 may include stacking additional IC dies (e.g., including the die 115-n), and/or forming additional thermal compression material layers 170 over and/or on at least one of the additional IC dies.

As shown in FIG. 8D, the series of operations 800 may include forming the casing 120. As an example, a mold tool may be used to form the casing 120 using an injection molding technique or a transfer molding technique. In some implementations, and as shown in FIG. 7D, the casing 120 may surround the pillar structures 155-2, the dies 115-1 through 115-n, and/or thermal compression material layers 170.

In some implementations, the series of operations 800 may include testing at least one of the dies 115-1 through 115-n. As an example, a testing tool (e.g., an automated test equipment tool) may perform a test operation that tests at least one of the dies 115-1 through 115-n by probing a tip 815 of the pillar structure 155-2 that is exposed at a surface of the casing 120. The test may be an electrical functionality test (e.g., a speed or reliability test), among other examples.

As indicated above, FIGS. 8A-8D are provided as an example. Other examples may differ from what is described with regards to FIGS. 8A-8D.

As described in connection with FIG. 1A, FIG. 1C, FIG. 2, FIG. 3, FIG. 5, and FIGS. 8A-8D, and in some implementations, a semiconductor device assembly (e.g., the apparatus 100 or the memory device 200) includes a substrate (e.g., the substrate 110), a first IC die (e.g., the die 115-1) over the substrate including a first plated hole (e.g., the through-hole 805 including the plating 810) that penetrates through the first IC die, and a second IC die (e.g., the die 115-n) over the first IC die including a second plated hole (e.g., the through-hole 805 including the plating 810) that penetrates through the second IC die. The semiconductor device assembly includes a pillar structure (e.g., the pillar structure 155-2) extending from the substrate that passes through the first plated hole and the second plated hole to electrically couple the first IC die, the second IC die, and the substrate.

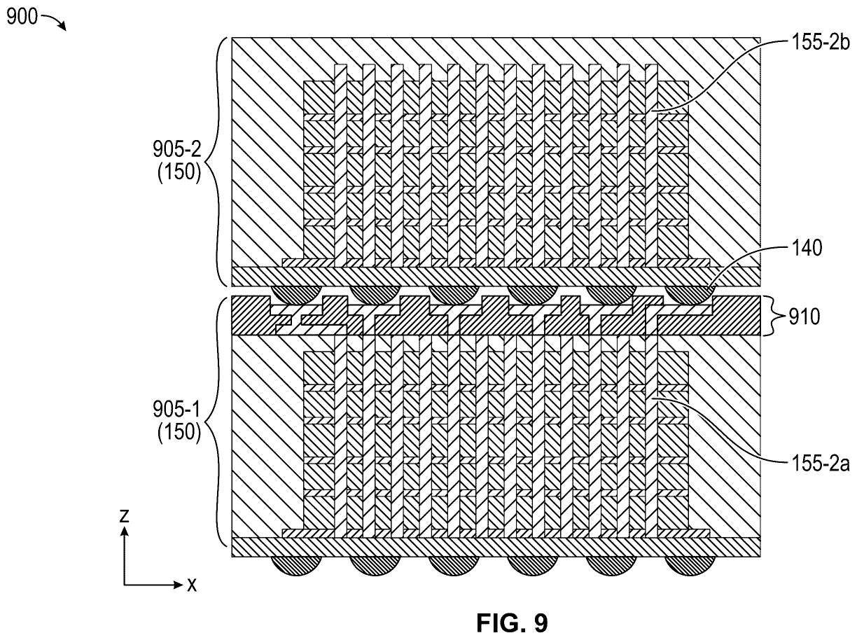

FIG. 9 is a diagram of an example integrated assembly 900 described herein. The integrated assembly 900 includes a semiconductor package 905-1 and a semiconductor package 905-2 that is stacked over the semiconductor package 905-1. The semiconductor packages 905-1 and 905-2 may be substantially similar to the implementation 150 described in connection with FIG. 1C and elsewhere herein.

As shown in FIG. 9, the semiconductor packages 905-1 and 905-2 may be electrically coupled using a redistribution layer (RDL) structure 910. The RDL structure 910 may include one or more layers of conductive traces (e.g., aluminum traces, copper traces, or nickel traces) interspersed with one or more dielectric layers (e.g., fiberglass epoxy resin layers, ceramic layers).

As shown in FIG. 9, interconnect structures (e.g., the solder balls 140) may be formed on a substrate of the semiconductor package 905-2 to electrically couple the pillar structure 155-2a with the pillar structure 155-2b through the RDL structure 910, thereby electrically coupling integrated circuitry (e.g., IC dies) of the semiconductor package 905-1 with integrated circuitry of the semiconductor package 905-2. Electrically coupling the integrated circuitry may electrically couple channels, inputs/outputs, and/or power inputs of memory integrated circuitry, among other examples.

As indicated above, FIG. 9 is provided as an example. Other examples may differ from what is described with regard to FIG. 9.

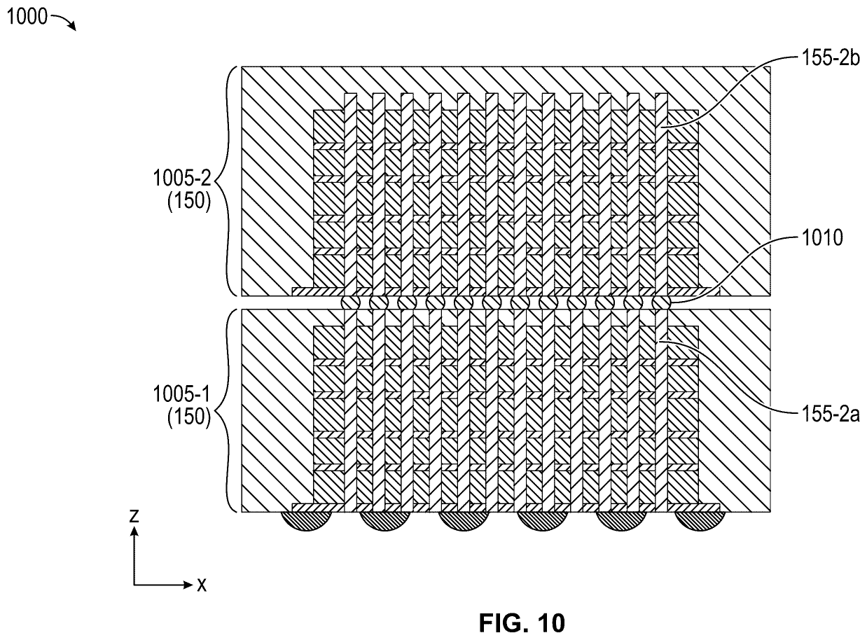

FIG. 10 is a diagram of an example integrated assembly 1000 described herein. The integrated assembly 1000 includes a semiconductor package 1005-1 and a semiconductor package 1005-2 that is stacked over the semiconductor package 1005-1. The semiconductor packages 1005-1 and 1005-2 may be substantially similar to the implementation 150 described in connection with FIG. 1C and elsewhere herein. In some implementations, the integrated assembly 1000 is referred to as a package-on-package assembly.

As shown in FIG. 10, the semiconductor package 1005-1 and the semiconductor package 1005-2 may be electrically coupled using at least one interconnect bump 1010. For example, and as shown in FIG. 10, the interconnect bump 1010 (e.g., a solder ball formed) directly conjoins with a bottom surface of the pillar structure 155-2b and with a top surface of the pillar structure 155-2a to electrically couple integrated circuitry (e.g., IC dies) of the semiconductor package 1005-2 with integrated circuitry of the semiconductor package 1005-1 Electrically coupling the integrated circuitry may electrically couple channels, inputs/outputs, and/or power inputs of memory integrated circuitry, among other examples.

As indicated above, FIG. 10 is provided as an example. Other examples may differ from what is described with regard to FIG. 10.

As described in connection with FIG. 1A, FIG. 1C, FIG. 2, FIG. 5, FIGS. 8A-8D, FIG. 9, and FIG. 10, and in some implementations, an integrated assembly (e.g., the integrated assembly 900 or the integrated assembly 1000) includes a first semiconductor package (e.g., the semiconductor package 905-1 or the semiconductor package 1005-1). The first semiconductor package includes a first IC die (e.g., the die 115-1) that is over a first substrate (e.g., the substrate 110) and that includes a first plated hole (e.g., the through-hole 805 and the plating 810) that penetrates through the first IC die. The first semiconductor package includes a second IC die (e.g., the die 115-n) that is over the first IC die and that includes a second plated hole (e.g., the through-hole 805 and the plating 810) that penetrates through the second IC die. The first semiconductor package includes and a first pillar structure (e.g., the pillar structure 155-2a) that extends from the first substrate and that passes through the first plated hole and the second plated hole to electrically couple the first IC die, the second IC die, and the first substrate. The integrated assembly includes a second semiconductor package (e.g., the semiconductor package 905-2 or the semiconductor package 1005-2) that is over the first semiconductor package and that is electrically coupled with the first semiconductor package. The second semiconductor package includes a second substrate (e.g., the substrate 110), a third IC die (e.g., the die 115-1) that is over the substrate and that includes a third plated hole (e.g., the through-hole 805 and the plating 810) that penetrates through the third IC die. The second semiconductor package includes a fourth IC die (e.g., the die 115-n) that is over the third IC die and that includes a fourth plated hole (e.g., the through-hole 805 and the plating 810) that penetrates through the fourth IC die. The second semiconductor package includes a second pillar structure (e.g., the pillar structure 155-2b) that extends from the second substrate and that passes through the third plated hole and the fourth plated hole to electrically couple the third IC die, the fourth IC die, and the second substrate.

In some implementations, a semiconductor device assembly includes a substrate; a first integrated circuit die over the substrate including a first recess that penetrates into a first edge of the first integrated circuit die; a second integrated circuit die over the first integrated circuit die including a second recess that penetrates into a second edge of the second integrated circuit die; and a pillar structure having a first bearing surface that supports the first integrated circuit die and a second bearing surface that supports the second integrated circuit die, wherein the pillar structure uses the first recess and the second recess to align perimeters of the first integrated circuit die and the second integrated circuit die, and wherein the first bearing surface and the second bearing surface separate the first integrated circuit die and the second integrated circuit die.

In some implementations, a semiconductor device assembly includes a substrate; a first integrated circuit die over the substrate including a first plated hole that penetrates through the first integrated circuit die; a second integrated circuit die over the first integrated circuit die including a second plated hole that penetrates through the second integrated circuit die; and a pillar structure extending from the substrate that passes through the first plated hole and the second plated hole to electrically couple the first integrated circuit die, the second integrated circuit die, and the substrate.

In some implementations, an integrated assembly includes a first semiconductor package, comprising: a first substrate; a first integrated circuit die over the first substrate including a first plated hole that penetrates through the first integrated circuit die; a second integrated circuit die over the first integrated circuit die including a second plated hole that penetrates through the second integrated circuit die; and a first pillar structure extending from the first substrate that passes through the first plated hole and the second plated hole to electrically couple the first integrated circuit die, the second integrated circuit die, and the first substrate; and a second semiconductor package over the first semiconductor package and electrically coupled with the first semiconductor package, comprising: a second substrate; a third integrated circuit die over the second substrate including a third plated hole that penetrates through the third integrated circuit die; a fourth integrated circuit die over the third integrated circuit die including a fourth plated hole that penetrates through the fourth integrated circuit die; and a second pillar structure extending from the second substrate that passes through the third plated hole and the fourth plated hole to electrically couple the third integrated circuit die, the fourth integrated circuit die, and the second substrate.

In some implementations, a method includes forming a pillar structure on a substrate; forming, along a first edge of a first integrated circuit die, a first recess; forming, along a second edge of a second integrated circuit die, a second recess; placing the first integrated circuit die over the substrate, wherein placing the first integrated circuit die over the substrate uses the first recess to align the first integrated circuit die with the pillar structure; and stacking the second integrated circuit die over the first integrated circuit die, wherein stacking the second integrated circuit die over the first integrated circuit die uses the second recess to align the second integrated circuit die with the first integrated circuit die, and wherein stacking the second integrated circuit die over the first integrated circuit die includes uses a bearing surface of the pillar structure to form a gap between the second integrated circuit die and the first integrated circuit die.

In some implementations, a method includes forming a pillar structure on a substrate; forming a first plated through-hole that penetrates through a first integrated circuit die; forming a second plated through-hole that penetrates through a second integrated circuit die; placing the first integrated circuit die over the substrate, wherein placing the first integrated circuit die over the substrate includes passing the pillar structure through the first plated through-hole and electrically coupling the first integrated circuit die with the substrate using the pillar structure; and stacking the second integrated circuit die over the first integrated circuit die, wherein stacking the second integrated circuit die over the first integrated circuit die includes passing the pillar structure through the second plated through-hole and electrically coupling the second integrated circuit die with the first integrated circuit die and the substrate using the pillar structure.

In some implementations, a method includes receiving a substrate; receiving a stacked die semiconductor package including a pillar structure that is used to align a first semiconductor die and a second semiconductor die that is stacked over the first semiconductor die; and joining the stacked die semiconductor package with the substrate.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a substrate;
a first integrated circuit die over the substrate including a first recess that penetrates into a first edge of the first integrated circuit die;
a second integrated circuit die over the first integrated circuit die including a second recess that penetrates into a second edge of the second integrated circuit die; and
a pillar structure having a first bearing surface that supports the first integrated circuit die and a second bearing surface that supports the second integrated circuit die,
wherein the pillar structure uses the first recess and the second recess to align perimeters of the first integrated circuit die and the second integrated circuit die, and
wherein the first bearing surface and the second bearing surface separate the first integrated circuit die and the second integrated circuit die.

2. The semiconductor device assembly of claim 1, wherein the pillar structure is a tapered pillar structure, and
wherein the first bearing surface and the second bearing surface are portions of an angled surface of the tapered pillar structure.

3. The semiconductor device assembly of claim 2, wherein the first recess and the second recess comprise angled surfaces that complement the portions of the angled surface of the tapered pillar structure.

4. The semiconductor device assembly of claim 1, wherein the pillar structure is a tiered pillar structure, and
wherein the first bearing surface and the second bearing surface are tiers of the tiered pillar structure.

5. The semiconductor device assembly of claim 1, wherein the pillar structure comprises:
a dielectric material.

6. The semiconductor device assembly of claim 5, wherein the dielectric material comprises:
a polyimide,
a polyetheretherketone,
a polycarbonate, or
a photopolymer resin.

7. The semiconductor device assembly of claim 1, further comprising:
a mold compound between co-facing surfaces of the first integrated circuit die and the second integrated circuit die.

8. The semiconductor device assembly of claim 1, further comprising:
a wire bond loop between co-facing surfaces of the first integrated circuit die and the second integrated circuit die.

9. The semiconductor device assembly of claim 1, wherein the pillar structure is included in an array of pillar structures along edges of the first integrated circuit die and the second integrated circuit die.

10. A semiconductor device assembly, comprising:
a substrate;
a first integrated circuit die over the substrate including a first plated hole that penetrates through the first integrated circuit die;
a second integrated circuit die over the first integrated circuit die including a second plated hole that penetrates through the second integrated circuit die; and
a pillar structure extending from the substrate that passes through the first plated hole and the second plated hole to electrically couple the first integrated circuit die, the second integrated circuit die, and the substrate.

11. The semiconductor device assembly of claim 10, wherein the first plated hole and the second plated hole have inside diameters that are approximately equal and substantially similar to an outside diameter of the pillar structure.

12. The semiconductor device assembly of claim 10, wherein the pillar structure is included in an array of pillar structures penetrating through the first integrated circuit die and the second integrated circuit die.

13. The semiconductor device assembly of claim 10, wherein the first plated hole or the second plated hole comprises:
copper plating,
aluminum plating, or
nickel plating.

14. The semiconductor device assembly of claim 10, wherein the pillar structure comprises a matrix material infused with:
copper powder,
aluminum powder, or
nickel powder.

15. The semiconductor device assembly of claim 10, further comprising:
a thermal compression material between the first integrated circuit die and the second integrated circuit die.

16. The semiconductor device assembly of claim 10, further comprising:
a casing that surrounds the first integrated circuit die and the second integrated circuit die,
wherein an end of the pillar structure is exposed at a surface of the casing.

17. An integrated assembly, comprising:
a first semiconductor package, comprising:
a first substrate;
a first integrated circuit die over the first substrate including a first plated hole that penetrates through the first integrated circuit die;
a second integrated circuit die over the first integrated circuit die including a second plated hole that penetrates through the second integrated circuit die; and
a first pillar structure extending from the first substrate that passes through the first plated hole and the second plated hole to electrically couple the first integrated circuit die, the second integrated circuit die, and the first substrate; and
a second semiconductor package over the first semiconductor package and electrically coupled with the first semiconductor package, comprising:
a second substrate;
a third integrated circuit die over the second substrate including a third plated hole that penetrates through the third integrated circuit die;
a fourth integrated circuit die over the third integrated circuit die including a fourth plated hole that penetrates through the fourth integrated circuit die; and
a second pillar structure extending from the second substrate that passes through the third plated hole and the fourth plated hole to electrically couple the third integrated circuit die, the fourth integrated circuit die, and the second substrate.

18. The integrated assembly of claim 17, further comprising:
a redistribution structure between the second semiconductor package and the first semiconductor package that electrically couples the second semiconductor package with the first semiconductor package.

19. The integrated assembly of claim 17, further comprising:
an interconnect bump that conjoins with a bottom surface of the second pillar structure and a top surface of the first pillar structure to electrically couple the second semiconductor package with the first semiconductor package.

20. A method, comprising:
forming a pillar structure on a substrate;
forming, along a first edge of a first integrated circuit die, a first recess;
forming, along a second edge of a second integrated circuit die, a second recess;
placing the first integrated circuit die over the substrate,
wherein placing the first integrated circuit die over the substrate uses the first recess to align the first integrated circuit die with the pillar structure; and
stacking the second integrated circuit die over the first integrated circuit die,
wherein stacking the second integrated circuit die over the first integrated circuit die uses the second recess to align the second integrated circuit die with the first integrated circuit die, and
wherein stacking the second integrated circuit die over the first integrated circuit die uses a bearing surface of the pillar structure to form a gap between the second integrated circuit die and the first integrated circuit die.

21. The method of claim 20, wherein forming the pillar structure includes:
forming the pillar structure using a three-dimensional printing operation.

22. The method of claim 20, wherein forming the first recess or the second recess includes:
forming the first recess or the second recess using a laser ablation operation,
forming the first recess or the second recess using an etching operation, or
forming the first recess or the second recess using a grinding operation.

23. The method of claim 20, wherein forming the pillar structure includes forming a tapered pillar structure having an angled surface, and wherein forming the first recess and the second recess includes:
forming interior, angled surfaces that complement the angled surface of the pillar structure.

24. The method of claim 20, wherein forming the pillar structure includes forming a tiered pillar structure.

25. The method of claim 20, further comprising:
forming a wire bond loop in the gap between the first integrated circuit die and the second integrated circuit die.

26. The method of claim 20, further comprising:
forming a casing that fills the gap and that surrounds the first integrated circuit die, the second integrated circuit die, and the pillar structure.

27. The method of claim 20, further comprising:
forming interconnect structures on the substrate, and
joining the interconnect structures with a redistribution structure as part of forming a package-on-package assembly that includes the first integrated circuit die, the second integrated circuit die, and the pillar structure.

28. A method, comprising:
forming a pillar structure on a substrate;
forming a first plated through-hole that penetrates through a first integrated circuit die;
forming a second plated through-hole that penetrates through a second integrated circuit die;
placing the first integrated circuit die over the substrate,
wherein placing the first integrated circuit die over the substrate includes passing the pillar structure through the first plated through-hole and electrically coupling the first integrated circuit die with the substrate using the pillar structure; and
stacking the second integrated circuit die over the first integrated circuit die,
wherein stacking the second integrated circuit die over the first integrated circuit die includes passing the pillar structure through the second plated through-hole and electrically coupling the second integrated circuit die with the first integrated circuit die and the substrate using the pillar structure.

29. The method of claim 28, wherein forming the pillar structure includes:
forming the pillar structure using a three-dimensional printing operation.

30. The method of claim 28, further comprising:
forming a casing that surrounds the first integrated circuit die, the second integrated circuit die, and the pillar structure.

31. The method of claim 30, further comprising:
testing at least one of the first integrated circuit die and the second integrated circuit die by probing a tip of the pillar structure that is exposed at a surface of the casing.

32. The method of claim 28, further comprising:
forming interconnect structures of the substrate, and
joining the interconnect structures with a redistribution structure as part of forming a package-on-package assembly that includes the first integrated circuit die, the second integrated circuit die, and the pillar structure.

33. The method of claim 28, wherein the pillar structure is a first pillar structure, and further comprising:
joining the first pillar structure with a second pillar structure as part of forming a package-on-package assembly that includes the first integrated circuit die, the second integrated circuit die, the first pillar structure, and the second pillar structure.

34. The method of claim 33, wherein joining the first pillar structure and the second pillar structure includes:
joining the first pillar structure and the second pillar structure using an interconnect bump that directly couples an end of the first pillar structure with an end of the second pillar structure.

35. The method of claim 28, further comprising:
forming a thermal compression material between the first integrated circuit die and the second integrated circuit die.
